(19) United States
(12) Patent Application Publication
(10) Pub. No.: US 2026/0299532 A1
(43) Pub. Date: Oct. 1, 2026

(54) NEURON NETWORK-BASED BATTERY MANAGEMENT METHOD, SYSTEM, AND DEVICE

(71) Applicant: SHENZHEN LEQI INNOVATION CO., LTD., SHENZHEN (CN)

(72) Inventor: JINXU LAI, SHENZHEN (CN)

(21) Appl. No.: 19/575,902

(22) Filed: Mar. 23, 2026

(30) Foreign Application Priority Data
Mar. 26, 2025 (CN) 202510367516.8

(51) Int. Cl. G05B 13/02; H01M 10/42

(52) U.S. Cl. CPC G05B 13/027; H01M 10/425; H01M 2010/4271

(57) ABSTRACT

A neuron network-based battery management method includes: obtaining real-time battery data of a battery, and inputting the real-time battery data into a preset fault diagnosis model; receiving a fault probability output by the preset fault diagnosis model based on the real-time battery data; determining whether the fault probability is greater than a preset threshold; and in response to determining that the fault probability is greater than the preset threshold, generating detailed fault information based on the real-time battery data and the fault probability, and retrieving an optimal repair strategy based on the detailed fault information to repair the battery.

### TECHNICAL FIELD

The present disclosure relates to the technical field of battery management, and in particular, to a neuron network-based battery management method, a neuron network-based battery management system, and a neuron network-based battery management device.

### BACKGROUND

With the rapid advancement of photography and live streaming, various shooting devices have seen widespread adoption. As an important power supply component, the effectiveness of battery management is particularly important. These battery management methods manage batteries and play a positive role in battery lifespan, safety, performance, and efficiency, thereby enhancing the overall value of battery usage.

However, battery management methods found in related art primarily rely on simple power monitoring and basic charge/discharge control strategies. Although these approaches can maintain basic battery usage to some extent, they come with many limitations. For example, such methods cannot accurately predict potential faults during battery use, nor can they respond promptly once a failure occurs. This often results in reduced overall battery performance and a shortened service life.

Therefore, it is necessary to provide a battery management method capable of improving the overall performance of a battery and extending its service life.

### SUMMARY

The present disclosure provides a neuron network-based battery management method, a neuron network-based battery management system, and a neuron network-based battery management device, aiming to address the issues of decline in battery performance during use and shortened service life of the battery in the related art.

To realize the above objective, the present disclosure provides a neuron network-based battery management method, including: obtaining real-time battery data of a battery, and inputting the real-time battery data into a preset fault diagnosis model; receiving a fault probability output by the preset fault diagnosis model based on the real-time battery data; determining whether the fault probability is greater than a preset threshold; and in response to determining that the fault probability is greater than the preset threshold, generating detailed fault information based on the real-time battery data and the fault probability, and retrieving a target repair strategy based on the detailed fault information to repair the battery.

In some embodiments, before obtaining the real-time battery data of the battery, the neuron network-based battery management method further includes: obtaining historical battery data of the battery; filtering the historical battery data to obtain preprocessed battery data; labeling the preprocessed battery data according to a labeling instruction to obtain labeled battery data, wherein the labeled battery data comprises normal battery data and abnormal battery data; and training an initial fault diagnosis model using the labeled battery data to obtain the preset fault diagnosis model.

In some embodiments, after receiving the fault probability output by the preset fault diagnosis model based on the real-time battery data, the neuron network-based battery management method further includes: updating the historical battery data based on the real-time battery data, and performing the operation of filtering the historical battery data to obtain the preprocessed battery data.

In some embodiments, the operation of retrieving a target repair strategy based on the detailed fault information to repair the battery includes: analyzing the detailed fault information to determine a fault type; querying a preset repair strategy library based on the fault type to obtain repair strategies; obtaining a success rate of each of the repair strategies, and sorting the success rates in a descending order; determining a first repair strategy as the target repair strategy, wherein the first repair strategy is the repair strategy corresponding to the success rate ranked first in the descending order; and repairing the battery according to the target repair strategy.

In some embodiments, after repairing the battery according to the target repair strategy, the neuron network-based battery management method further includes: obtaining a current battery status of the battery; comparing the current battery status with a preset normal status to determine whether the battery has been successfully repaired; and in response to determining that the battery has been successfully repaired, updating the success rate of the target repair strategy, and recording information about a successful repair of the battery.

In some embodiments, after determining whether the battery has been successfully repaired, the neuron network-based battery management method further includes: in response to determining that the battery fails to be successfully repaired, generating a maintenance recommendation based on the fault type and displaying the maintenance recommendation; or, in response to determining that the battery fails to be successfully repaired, obtaining a second repair strategy and repairing the battery according to the second repair strategy, wherein the second repair strategy is the repair strategy corresponding to the success rate ranked second in the descending order.

In some embodiments, the battery includes a plurality of monomer batteries, and the neuron network-based battery management method further includes: acquiring a current voltage of each of the plurality of monomer batteries; performing an average calculation on the current voltages of the plurality of monomer batteries to obtain a current average voltage; comparing the current voltage of each monomer battery with the current average voltage; if the current voltage of the monomer battery is greater than the current average voltage, controlling an equalization circuit to discharge the monomer battery until the current voltage of the monomer battery equals the current average voltage; and if the current voltage of the monomer battery is less than the current average voltage, controlling the equalization circuit to charge the monomer battery until the current voltage of the monomer battery equals the current average voltage.

In some embodiments, the neuron network-based battery management method further includes: detecting an electrical current parameter of a charging current, and obtaining a current battery status of the battery; adjusting the electrical current parameter based on the current battery status to obtain a target electrical current parameter; and adjusting the charging current based on the target electrical current parameter, and supplying the adjusted charging current to the battery.

The present disclosure further provides a neuron network-based battery management system, including a neuron chip and a battery. The neuron chip is configured to configure and run a neuron network. The neuron network-based battery management system is configured to perform the neuron network-based battery management method described in any one of the foregoing embodiments.

The present disclosure further provides a neuron network-based battery management device, including: at least one processor, and a memory communicated with the at least one processor. The memory stores computer-executable instructions, when executed by at least one processor, cause the at least one processor to perform the neuron network-based battery management method described in any one of the foregoing embodiments.

According to the present disclosure, a preset fault diagnosis model is pre-trained on a neuron network. The neuron network obtains real-time battery data of a battery, detects the real-time battery data using the preset fault diagnosis model to determine a fault probability indicating a fault from the real-time battery data, and compares the fault probability with a preset threshold to determine whether a fault occurs in the battery. If a fault occurs, the neuron network retrieves a corresponding repair strategy to perform battery repair, thereby improving the overall performance and service life of the battery. Further, by incorporating the neuron network into battery management, both the effectiveness and the intelligence level of battery management are enhanced.

### BRIEF DESCRIPTION OF THE DRAWINGS

FIG. 1 is a schematic flowchart diagram of a neuron network-based battery management method according to an embodiment of the present disclosure.

FIG. 2 is a schematic flowchart diagram of a neuron network-based battery management method according to another embodiment of the present disclosure.

FIG. 3 is a schematic flowchart diagram of a neuron network-based battery management method according to still another embodiment of the present disclosure.

FIG. 4 is a schematic flowchart diagram of a neuron network-based battery management method according to yet another embodiment of the present disclosure.

FIG. 5 is a schematic flowchart diagram of a neuron network-based battery management method according to yet another embodiment of the present disclosure.

FIG. 6 is a schematic flowchart diagram of a neuron network-based battery management method according to yet another embodiment of the present disclosure.

FIG. 7 is a schematic structural diagram of a neuron network-based battery management system according to an embodiment of the present disclosure.

FIG. 8 is a schematic structural diagram of a neuron network-based battery management device according to an embodiment of the present disclosure.

The realization of the objectives, functional features, and advantages of the present disclosure will be further described in conjunction with the embodiments and with reference to the accompanying drawings.

### DETAILED DESCRIPTION OF THE EMBODIMENTS

The technical solutions in the embodiments of the present disclosure will be described clearly and completely with reference to the accompanying drawings in the embodiments of the present disclosure. Obviously, the described embodiments are only a part of the embodiments of the present disclosure rather than all of them. Based on the embodiments in the present disclosure, all other embodiments obtained by those skilled in the art without creative work shall fall within the scope of protection of the present disclosure.

It should be noted that all directional indications (such as up, down, left, right, front, back) in the embodiments of the present disclosure are merely used to explain relative position relationships or motion conditions between the components in a specific attitude (as shown in the drawings). The directional indication changes as the specific attitude changes.

It should also be noted that when an element is referred to as being “mounted on” or “disposed on” another element, it may be directly on the other element, or intervening elements may also be present. When an element is referred to as being “connected to” another element, it may be directly connected to the other element, or intervening elements may also be present.

Moreover, the terms “first”, “second”, and the like in the present disclosure are merely used for description and cannot be understood as indicating or implying their relative importance or as implicitly indicating the quantity of the technical features indicated. Thus, the feature defined by “first” or “second” may explicitly or implicitly include at least one such feature. In addition, the technical solutions of various embodiments may be combined with each other, but must be based on that the combined technical solutions can be implemented by those skilled in the art. When the combination of the technical solutions is contradictory or impossible to realize, it shall be considered that such combination does not exist and is not within the scope of protection of the present disclosure.

To achieve the above objectives, the present disclosure provides a neuron network-based battery management method, including:

Step S110: obtaining real-time battery data of a battery, and inputting the real-time battery data into a preset fault diagnosis model;

Step S120: receiving a fault probability output by the preset fault diagnosis model based on the real-time battery data;

Step S130: determining whether the fault probability is greater than a preset threshold; and

Step S140: generating, in response to determining that the fault probability is greater than the preset threshold, detailed fault information based on the real-time battery data and the fault probability, and retrieving a target repair strategy based on the detailed fault information to repair the battery.

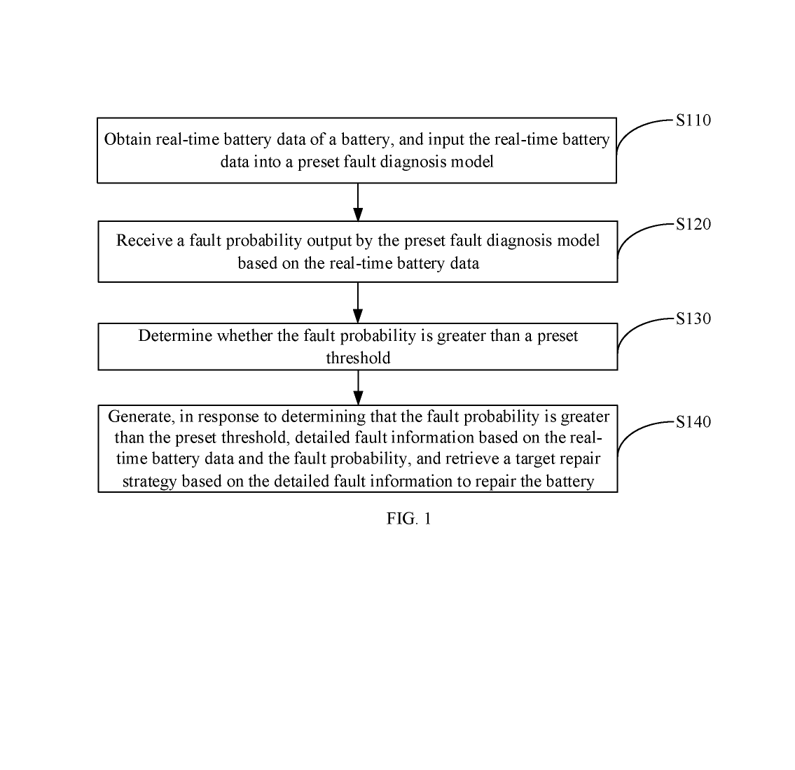

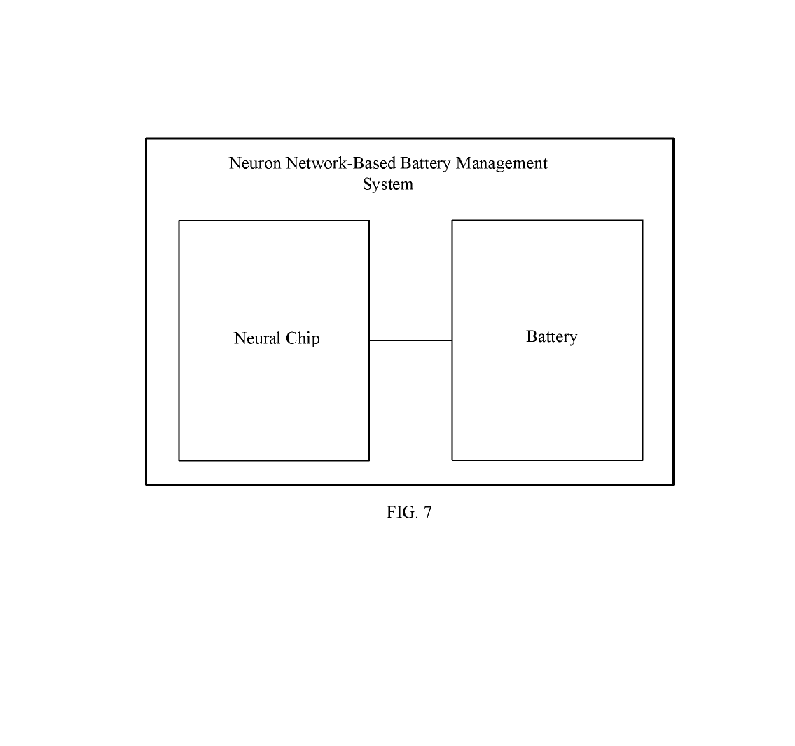

In the embodiments, with reference to FIGS. 1 and 7, the neuron network-based battery management method is applied to a neuron network-based battery management system. The neuron network-based battery management system is configured to manage a battery to improve the overall performance and service life of the battery. The neuron network is a computational model that mimics the structure and function of a biological neuron network. It consists of a large number of interconnected neurons and accomplishes various tasks by learning from and processing data. The neuron network-based battery management system includes a neuron chip and a battery. The neuron chip is configured to configure and run the neuron network. The neuron network learns by obtaining battery data from a large number of batteries, thereby realizing the processing of real-time battery data to implement various battery management tasks. In the embodiments, all steps of the method are performed by the neuron network configured on the neuron chip.

It will be appreciated that a neuron network may include neurons, synaptic connections, and a network structure. Neurons are the fundamental processing units of the neuron network, analogous to biological neurons. Each neuron receives multiple input signals, performs a weighted summation of these signals, processes the result through an activation function, and then generates an output signal. Synaptic connections serve as channels for information exchange between neurons, enabling information transmission from one neuron to another. Each connection is assigned with a weight value that indicates the importance of that connection in information transmission. The weight values are continuously adjusted during the learning process of the neuron network to optimize the performance of the neuron network. The network structure is composed of multiple neurons organized in specific layers and connection patterns. Common architectures include feedforward neuron networks, recurrent neuron networks, and convolutional neuron networks, and the like.

In some embodiments, the battery is connected to the neuron chip, and the neuron chip is configured to obtain battery data from the battery. The neuron network is configured on the neuron chip and can obtain the battery data through the neuron chip. The neuron network obtains the real-time battery data from the battery, and a preset fault diagnosis model that has been trained in advance is stored in the neuron network. The neuron network inputs the real-time battery data into the preset fault diagnosis model, allowing the preset fault diagnosis model to process the real-time battery data.

After processing the real-time battery data, the preset fault diagnosis model outputs a result. For example, the preset fault diagnosis model outputs a fault probability corresponding to the real-time battery data. After the preset fault diagnosis model outputs the fault probability, the neuron network receives the fault probability generated by the preset fault diagnosis model based on the real-time battery data.

After receiving the fault probability, the neuron network determines whether the fault probability is greater than a preset threshold. If the fault probability is greater than the preset threshold, it indicates that the battery has a fault. If the fault probability is lower than the preset threshold, it indicates that the battery has no fault.

In response to determining that the fault probability is greater than the preset threshold, the neuron network generates detailed fault information based on the real-time battery data and the fault probability, and displays the detailed fault information. In some embodiments, the neuron network further retrieves a target repair strategy based on the detailed fault information, to perform repair on the battery according to the target repair strategy.

In response to determining that the fault probability is lower than the preset threshold, the neuron network continues to monitor the fault probability. That is, the neuron network continues to obtain real-time battery data of the battery and input the real-time battery data into the preset fault diagnosis model. This enables detection of faults in time in the battery, thereby enhancing the overall performance and service life of the battery.

In the embodiments, a preset fault diagnosis model is pre-trained on a neuron network. The neuron network obtains real-time battery data of a battery, detects the real-time battery data using the preset fault diagnosis model to determine a fault probability indicating a fault from the real-time battery data, and compares the fault probability with a preset threshold to determine whether a fault occurs in the battery. If a fault occurs, the neuron network retrieves a corresponding repair strategy to perform battery repair, thereby improving the overall performance and service life of the battery. Further, by incorporating the neuron network into battery management, both the effectiveness and the intelligence level of battery management are enhanced.

In some embodiments, before obtaining the real-time battery data of the battery, the method further includes:

Step S150: obtaining historical battery data of the battery;

Step S151: filtering the historical battery data to obtain preprocessed battery data;

Step S152: labeling the preprocessed battery data according to a labeling instruction, to obtain labeled battery data, wherein the labeled battery data includes normal battery data and abnormal battery data; and

Step S153: training an initial fault diagnosis model based on the labeled battery data to obtain the preset fault diagnosis model.

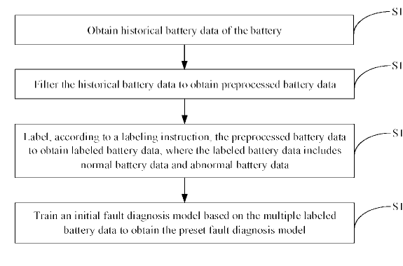

In the embodiments, with reference to FIG. 2, the neuron network trains the preset fault diagnosis model in advance before performing Step S110. The neuron network can continuously acquire real-time battery data of the battery. A large amount of battery data can be obtained in a relatively long duration of continuous acquisition. The neuron network stores this large amount of battery data to form the historical battery data. That is, the historical battery data includes a plurality of battery data. The neuron network can train the preset fault diagnosis model by using the historical battery data of the battery.

After obtaining the historical battery data, the neuron network first performs filtering processing on the historical battery data. For example, the historical battery data is processed using a moving average filtering algorithm or a Kalman filtering algorithm to remove abnormal noise from the historical battery data. After the neuron network filters the historical battery data, the preprocessed battery data is obtained.

After obtaining the preprocessed battery data, the neuron network further labels the preprocessed battery data. The neuron network labels the preprocessed battery data according to the labeling instruction, to generate labeled battery data, including normal battery data and abnormal battery data. In some embodiments, the labeling instruction is generated based on labeling information input by a user. The user-input labeling information can be classified and labeled according to different diagnostic requirements. For example, battery data under normal operating conditions is labeled as “normal battery data”, while battery data under abnormal conditions such as overvoltage, undervoltage, overcurrent, overtemperature, and short circuit is labeled as “abnormal battery data”. In some embodiments, the abnormal battery data is further subdivided, that is, labeled as corresponding fault categories according to abnormal conditions such as overvoltage, undervoltage, overcurrent, overtemperature, and short circuit. That is, the abnormal battery data can include overvoltage battery data, undervoltage battery data, overcurrent battery data, overtemperature battery data, short-circuit battery data, and the like.

After obtaining the labeled battery data, the neuron network trains the initial fault diagnosis model by using the labeled battery data, to obtain the preset fault diagnosis model. For example, a large amount of normal battery data and abnormal battery data is input into the initial fault diagnosis model, and the initial fault diagnosis model then learns and trains based on the data, thereby understanding which battery data is normal and which is abnormal. As such, the preset fault diagnosis model is obtained.

In some embodiments, after receiving the fault probability output by the preset fault diagnosis model based on the real-time battery data, the method further includes:

updating the historical battery data based on the real-time battery data, and performing the step of filtering the historical battery data to obtain preprocessed battery data.

In the embodiments, after performing Step S120, the neuron network updates the historical battery data. After receiving the fault probability output by the preset fault diagnosis model based on the real-time battery data, the neuron network further updates the historical battery data. In some embodiments, updating historical battery data based on the real-time battery data is implemented by adding the real-time battery data to the historical battery data, or by replacing the earliest obtained battery data in the historical battery data with the real-time battery data. After updating the historical battery data, the neuron network performs the step of filtering the historical battery data to obtain preprocessed battery data. That is, the preset fault diagnosis model is retrained and updated. For example, as time progresses and new battery data accumulates, the neuron network periodically retrains the preset fault diagnosis model or updates the preset fault diagnosis model online. This can be achieved through incremental learning, i.e., training only on the new battery data while fine-tuning part of the weight values of the original model; alternatively, a complete retraining is performed using a combination of new battery data and old battery data, while keeping the model structure unchanged or adjusting the structure based on performance evaluation results.

In some embodiments, the operation of retrieving a target repair strategy based on the detailed fault information to repair the battery includes:

Step S160: analyzing the detailed fault information to determine a fault type;

Step S161: querying a preset repair strategy library based on the fault type to obtain a plurality of repair strategies;

Step S162: obtaining a success rate of each of the repair strategies, and sorting the success rates in a descending order;

Step S163: determining a first repair strategy as the target repair strategy, wherein the first repair strategy is the repair strategy corresponding to the success rate ranked first in the descending order; and

Step S164: repairing the battery according to the target repair strategy.

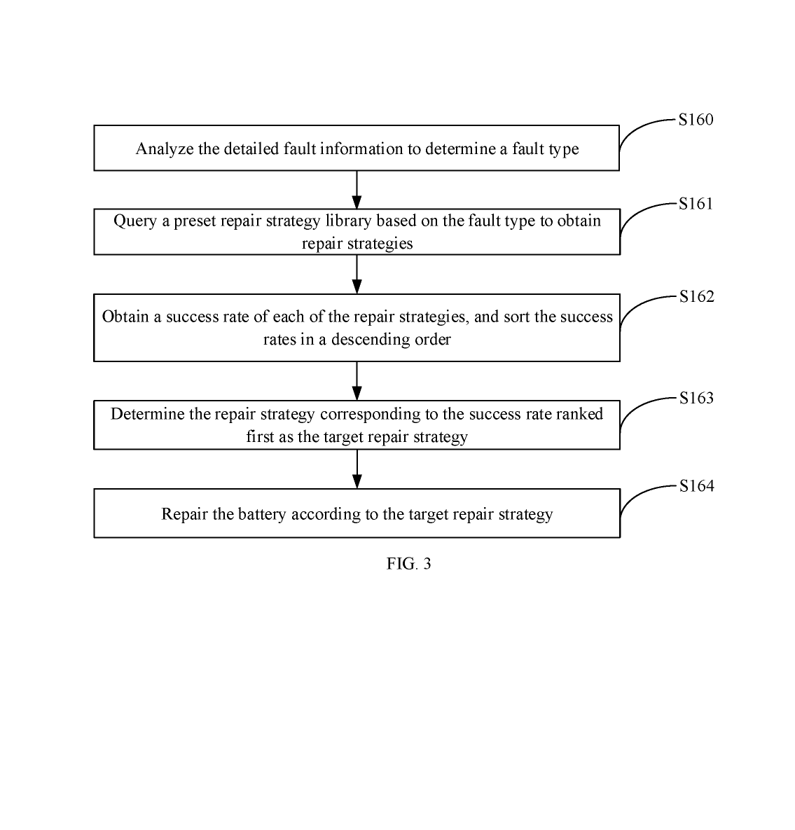

In the embodiments, with reference to FIG. 3, when performing Step S140, the neuron network retrieves the target repair strategy from a preset repair strategy library. In some embodiments, the preset repair strategy library is pre-configured by a user on the neuron network. One fault type can correspond to multiple repair strategies, and each repair strategy is associated with a success rate for repairing the fault type. The neuron network first analyzes the detailed fault information to determine the fault type. For example, the fault type includes overvoltage fault, undervoltage fault, overcurrent fault, overtemperature fault, short-circuit fault, and the like.

After determining the fault type, the neuron network queries the preset repair strategy library based on the fault type, to obtain multiple repair strategies. For example, if the fault type is overvoltage fault, there are various overvoltage faults, such as charging overvoltage, load abnormality overvoltage, environmental factor overvoltage, and the like. Each of the overvoltage faults corresponds to one or more repair strategies.

After obtaining the multiple repair strategies, the neuron network obtains the success rates of the multiple repair strategies and arranges the success rates in a descending order. The success rate of each repair strategy can be obtained through repair simulations. For example, if a total of ten overvoltage faults occur in a simulated battery, and the preset repair strategy library is queried to obtain repair strategies A, B, and C; then the strategies A, B, and C are respectively used to repair the ten overvoltage faults. If strategy A successfully repairs 9 faults, its success rate is 90%. Similarly, if strategy B successfully repairs all 10 faults, its success rate is 100%; and if strategy C successfully repairs 5 faults, its success rate is 50%. Alternatively, the success rate of each repair strategy can also be obtained based on the historical number of times that the repair strategy has been used and the number of successful repairs achieved using that repair strategy.

After sorting the success rates of the repair strategies in the descending order, the neuron network determines the repair strategy corresponding to the success rate ranked first as the target repair strategy. That is, the neuron network determines the repair strategy with the highest success rate as the target repair strategy. Then, the neuron network performs a repair on the fault type of the battery according to the target repair strategy.

In some embodiments, after repairing the battery based on the target repair strategy, the neuron network-based battery management method further includes:

Step S170: obtaining a current battery status of the battery;

Step S171: comparing the current battery status with a preset normal status to determine whether the battery has been successfully repaired; and

Step S172: updating, in response to determining that the battery has been successfully repaired, the success rate of the target repair strategy, and recording information about the successful repair of the battery.

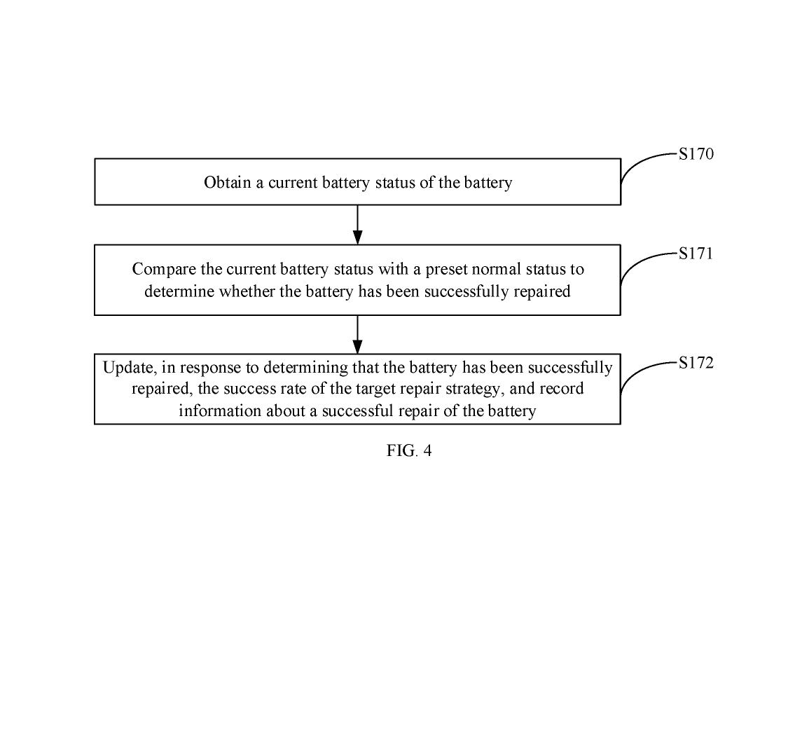

In the embodiments, with reference to FIG. 4, after performing Step S164, the neuron network further determines whether the battery has been successfully repaired. The neuron network obtains the current battery status of the battery, compares the current battery status with the preset normal status to determine whether the battery has been successfully repaired. If the current battery status matches the preset normal status, it indicates that the battery has been successfully repaired; if the current battery status fails to match the preset normal status, it indicates that the repair is failed.

In response to determining that the battery has been successfully repaired, the neuron network updates the success rate of the target repair strategy, i.e., increases the success rate of the target repair strategy, and records information about the successful battery repair. In some embodiments, the neuron network displays the information about the successful repair of the battery.

In some embodiments, after determining whether the battery has been successfully repaired, the neuron network-based battery management method further includes:

in response to determining that the battery has not been successfully repaired, generating a maintenance recommendation based on the fault type, and displaying the maintenance recommendation; or

in response to determining that the battery has not been successfully repaired, obtaining a second repair strategy, and repairing the battery according to the second repair strategy, where the second repair strategy is the repair strategy corresponding to the success rate ranked second in the descending order.

In the embodiments, after performing Step S171, the neuron network is further configured to implement two alternative approaches if the battery has not been successfully repaired. In response to determining that the battery has not been successfully repaired, the neuron network generates a maintenance recommendation based on the fault type and displays the maintenance recommendation; or, the neuron network obtains a second repair strategy and perform secondary repair on the battery according to the second repair strategy, where the second repair strategy is the repair strategy corresponding to the success rate ranked second in the descending order.

In some embodiments, which processing approach to take when the battery fails to be successfully repaired may be determined based on the number of repair strategies. For example, if the battery fails to be successfully repaired, multiple repair strategies arranged in the descending order can be applied sequentially for repair. That is, if the battery fails to be successfully repaired according to the second repair strategy, the third repair strategy is applied. If the battery fails to be successfully repaired according to the third repair strategy, the fourth repair strategy is applied, and so forth, until the repair strategy ranked last is reached. Here, the third repair strategy corresponds to the success rate ranked third in the descending order, and the fourth repair strategy corresponds to the success rate ranked fourth in the descending order. If the repair of the battery is not successful even after applying the repair strategy with the lowest ranking in the descending order, a maintenance recommendation is generated based on the fault type and displayed.

In some embodiments, the battery includes a plurality of monomer batteries, and the neuron network-based battery management method further includes:

Step S180: acquiring a current voltage of each monomer battery;

Step S181: performing an average calculation on the current voltages of the plurality of monomer batteries to obtain a current average voltage;

Step S182: comparing the current voltage of each monomer battery with the current average voltage;

Step S183: if the current voltage of the monomer battery is greater than the current average voltage, controlling an equalization circuit to discharge the monomer battery until the current voltage of the monomer battery equals the current average voltage; and

Step S184: if the current voltage of the monomer battery is less than the current average voltage, controlling an equalization circuit to charge the monomer battery until the current voltage of the monomer battery equals the current average voltage.

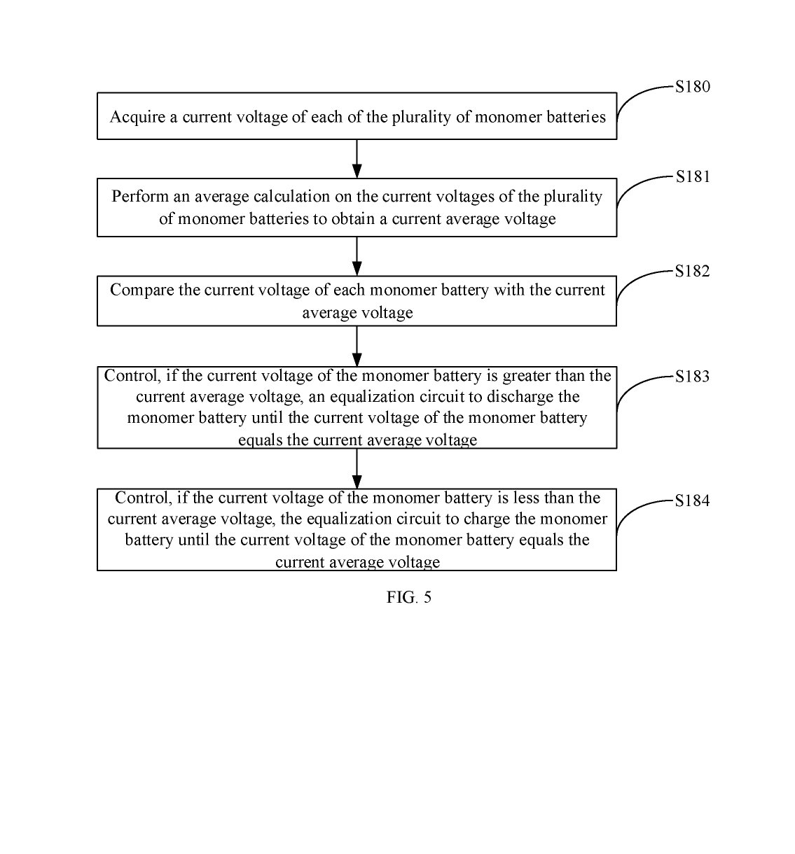

In the embodiments, with reference to FIG. 5, the neuron network-based battery management method further includes performing voltage equalization. The battery includes a plurality of monomer batteries which are connected to an equalization circuit. The neuron network controls the equalization circuit to charge or discharge the plurality of monomer batteries. When voltage imbalance occurs in some of the monomer batteries, it results in significant fluctuations in the overall voltage of the battery, consequently affecting the overall performance and service life of the battery. By equalizing the voltage of each monomer battery, the neuron network helps ensure the overall performance and service life of the battery. The neuron network acquires the current voltage of each monomer battery, and performs an averaging operation on the current voltages of the plurality of monomer batteries to obtain the current average voltage. For example, the current average voltage is calculated by summing the current voltages of the plurality of monomer batteries and then dividing the total by the number of the plurality of monomer batteries.

After obtaining the current average voltage, the neuron network compares the current voltage of each monomer battery with the current average voltage.

If the current voltage of a monomer battery is greater than the current average voltage, the neuron network controls the equalization circuit to discharge that monomer battery until the current voltage of the monomer battery becomes equal to the current average voltage, at which point the discharging is stopped. If the current voltage of a monomer battery is less than the current average voltage, the neuron network controls the equalization circuit to charge that monomer battery until the current voltage of the monomer battery becomes equal to the current average voltage, at which point the charging is stopped.

In some embodiments, the neuron network-based battery management method further includes:

Step S190: detecting an electrical current parameter of a charging current, and obtaining a current battery status of the battery;

Step S191: adjusting the electrical current parameter based on the current battery status to obtain a target electrical current parameter; and

Step S192: adjusting the charging current based on the target electrical current parameter, and supplying the adjusted charging current to the battery.

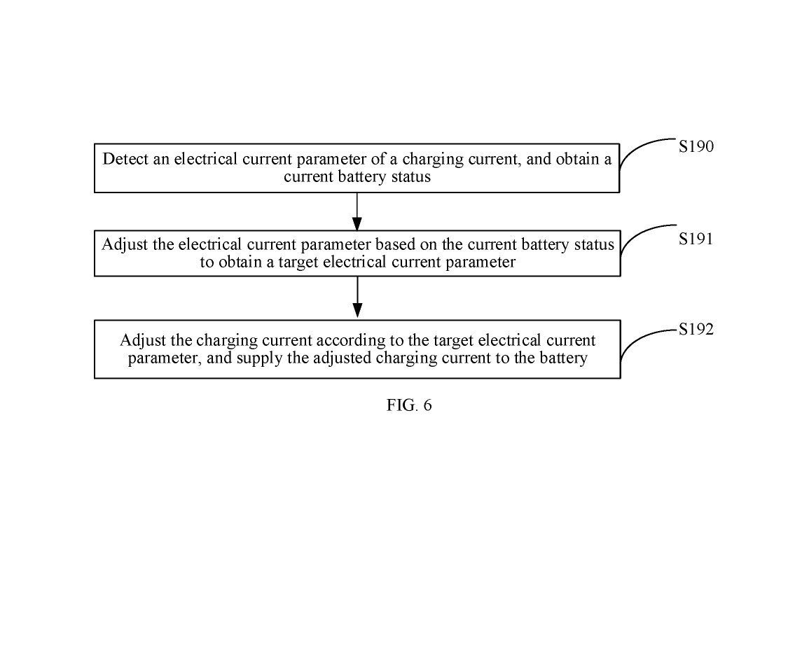

In the embodiments, referring to FIG. 6, the neuron network-based battery management method further includes performing charging control. During charging of the battery, the neuron network first detects the electrical current parameter of the charging current and obtains the current battery status. Then, the neuron network adjusts the electrical current parameter based on the current battery status to obtain the target electrical current parameter. Finally, the neuron network adjusts the charging current based on the target electrical current parameter, and supplies the adjusted charging current to the battery.

In the present disclosure, a preset fault diagnosis model is pre-trained on a neuron network. The neuron network obtains real-time battery data of a battery, detects the real-time battery data using the preset fault diagnosis model to determine a fault probability indicating a fault from the real-time battery data, and compares the fault probability with a preset threshold to determine whether a fault occurs in the battery. If a fault occurs, the neuron network retrieves a corresponding repair strategy to perform battery repair, thereby improving the overall performance and service life of the battery. Further, by incorporating the neuron network into battery management, both the effectiveness and the intelligence level of battery management are enhanced.

The present disclosure further provides a neuron network-based battery management system including a neuron chip and a battery. The neuron chip is configured to configure and run a neuron network. The neuron network-based battery management system is configured to perform the neuron network-based battery management method described in any one of the foregoing embodiments.

In the embodiments, with reference to FIG. 7, the neuron network-based battery management system includes a neuron chip and a battery. The neuron chip is configured to configure and run a neuron network. The neuron network learns based on battery data obtained from a large number of batteries, thereby realizing processing of real-time battery data to implement various battery management tasks.

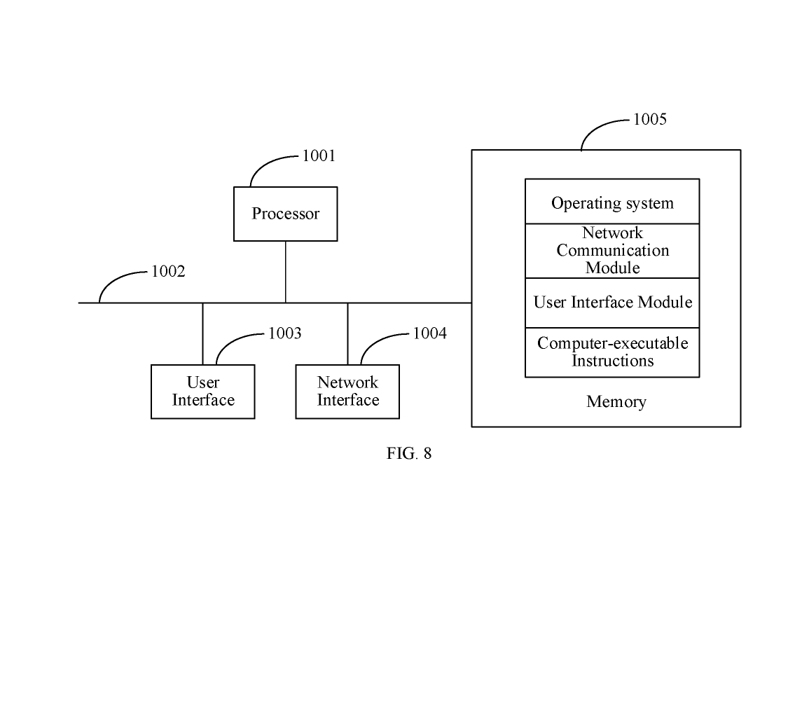

The present disclosure further provides a neuron network-based battery management device. Referring to FIG. 8, FIG. 8 is a schematic structural diagram of a neuron network-based battery management device in a hardware operating environment according to an embodiment of the present disclosure.

In some embodiments, the neuron network-based battery management device includes at least one processor configured to execute the neuron network-based battery management method. As shown in FIG. 8, the neuron network-based battery management device includes: a processor 1001 (e.g., a CPU), a network interface 1004, a user interface 1003, a memory 1005, and a communication bus 1002. The communication bus 1002 is configured to enable connection and communication among these components. The user interface 1003 includes a display unit and an input unit such as a keyboard. In some embodiments, the user interface 1003 further includes standard wired or wireless interfaces. The network interface 1004 includes standard wired or wireless interfaces (e.g., a WI-FI interface). The memory 1005 is a high-speed Random Access Memory (RAM) or a non-volatile memory, such as a disk memory. In some embodiments, the memory 1005 is a storage member independent of the processor 1001.

It will be appreciated that the structure of the neuron network-based battery management device shown in FIG. 8 is not intended to limit the scope of the neuron network-based battery management device. The neuron network-based battery management device can include more or fewer components than those illustrated, combine certain components, or be arranged differently.

As shown in FIG. 8, the memory 1005 serves as a computer storage medium, including an operating system, a network communication module, a user interface module, and computer-executable instructions.

In the neuron network-based battery management device illustrated in FIG. 8, the network interface 1004 is configured to connect to a backend server and communicate with the backend server, the user interface 1003 is configured to connect to a client end (i.e., user end) and communicate with the client end, and the processor 1001 is configured to call the computer-executable instructions stored in the memory 1005. When the computer-executable instructions is called and executed by the processor 1001, the neuron network-based battery management method described in any one of the foregoing embodiments is implemented.

The present disclosure further provides a storage medium, storing computer-executable instructions. When the computer-executable instructions are executed by a processor, the neuron network-based battery management method described in any one of the foregoing embodiments is implemented.

The above are only some embodiments of the present disclosure, and neither the words nor the drawings can limit the protection scope of the present disclosure. Any equivalent structural transformation made by using the contents of the specification and the drawings of the present disclosure under the overall concept of the present disclosure, or directly/indirectly applied in other related technical fields are included in the protection scope of the present disclosure.

What is claimed is:

1. A neuron network-based battery management method, comprising:
obtaining real-time battery data of a battery, and inputting the real-time battery data into a preset fault diagnosis model;
receiving a fault probability output by the preset fault diagnosis model based on the real-time battery data;
determining whether the fault probability is greater than a preset threshold; and
in response to determining that the fault probability is greater than the preset threshold, generating detailed fault information based on the real-time battery data and the fault probability, and retrieving a target repair strategy based on the detailed fault information to repair the battery.

2. The neuron network-based battery management method of claim 1, wherein before obtaining the real-time battery data of the battery, the neuron network-based battery management method further comprises:
obtaining historical battery data of the battery;
filtering the historical battery data to obtain preprocessed battery data;
labeling the preprocessed battery data according to a labeling instruction to obtain labeled battery data, wherein the labeled battery data comprises normal battery data and abnormal battery data; and
training an initial fault diagnosis model using the labeled battery data to obtain the preset fault diagnosis model.

3. The neuron network-based battery management method of claim 2, wherein after receiving the fault probability output by the preset fault diagnosis model based on the real-time battery data, the neuron network-based battery management method further comprises:
updating the historical battery data based on the real-time battery data, and performing the operation of filtering the historical battery data to obtain the preprocessed battery data.

4. The neuron network-based battery management method of claim 1, wherein the operation of retrieving a target repair strategy based on the detailed fault information to repair the battery comprises:
analyzing the detailed fault information to determine a fault type;
querying a preset repair strategy library based on the fault type to obtain repair strategies;
obtaining a success rate of each of the repair strategies, and sorting the success rates in a descending order;
determining a first repair strategy as the target repair strategy, wherein the first repair strategy is the repair strategy corresponding to the success rate ranked first in the descending order; and
repairing the battery according to the target repair strategy.

5. The neuron network-based battery management method of claim 4, wherein after repairing the battery according to the target repair strategy, the neuron network-based battery management method further comprises:
obtaining a current battery status of the battery;
comparing the current battery status with a preset normal status to determine whether the battery has been successfully repaired; and
in response to determining that the battery has been successfully repaired, updating the success rate of the target repair strategy, and recording information about a successful repair of the battery.

6. The neuron network-based battery management method of claim 5, wherein after determining whether the battery has been successfully repaired, the neuron network-based battery management method further comprises:
in response to determining that the battery fails to be successfully repaired, generating a maintenance recommendation based on the fault type and displaying the maintenance recommendation;
or,
in response to determining that the battery fails to be successfully repaired, obtaining a second repair strategy and repairing the battery according to the second repair strategy, wherein the second repair strategy is the repair strategy corresponding to the success rate ranked second in the descending order.

7. The neuron network-based battery management method of claim 1, wherein the battery comprises a plurality of monomer batteries, and the neuron network-based battery management method further comprises:
acquiring a current voltage of each of the plurality of monomer batteries;
performing an average calculation on the current voltages of the plurality of monomer batteries to obtain a current average voltage;
comparing the current voltage of each monomer battery with the current average voltage;
if the current voltage of the monomer battery is greater than the current average voltage, controlling an equalization circuit to discharge the monomer battery until the current voltage of the monomer battery equals the current average voltage; and
if the current voltage of the monomer battery is less than the current average voltage, controlling the equalization circuit to charge the monomer battery until the current voltage of the monomer battery equals the current average voltage.

8. The neuron network-based battery management method of claim 1, further comprising:
detecting an electrical current parameter of a charging current, and obtaining a current battery status of the battery;
adjusting the electrical current parameter based on the current battery status to obtain a target electrical current parameter; and
adjusting the charging current based on the target electrical current parameter, and supplying the adjusted charging current to the battery.

9. A neuron network-based battery management system, comprising a neuron chip and a battery; wherein,
the neuron chip is configured to configure and run a neuron network; and the neuron network-based battery management system is configured to perform the neuron network-based battery management method of claim 1.

10. The neuron network-based battery management system of claim 9, wherein before obtaining the real-time battery data of the battery, the neuron network-based battery management system is further configured to:
obtain historical battery data of the battery;
filter the historical battery data to obtain preprocessed battery data;
label the preprocessed battery data according to a labeling instruction to obtain labeled battery data, wherein the labeled battery data comprises normal battery data and abnormal battery data; and
train an initial fault diagnosis model using the labeled battery data to obtain the preset fault diagnosis model.

11. The neuron network-based battery management system of claim 10, wherein after receiving the fault probability output by the preset fault diagnosis model based on the real-time battery data, the neuron network-based battery management system is further configured to:
update the historical battery data based on the real-time battery data, and performing the operation of filtering the historical battery data to obtain the preprocessed battery data.

12. The neuron network-based battery management system of claim 9, wherein the operation of retrieving a target repair strategy based on the detailed fault information to repair the battery comprises:
analyze the detailed fault information to determine a fault type;
query a preset repair strategy library based on the fault type to obtain repair strategies;
obtain a success rate of each of the repair strategies, and sorting the success rates in a descending order;
determine a first repair strategy as the target repair strategy, wherein the first repair strategy is the repair strategy corresponding to the success rate ranked first in the descending order; and
repair the battery according to the target repair strategy.

13. The neuron network-based battery management system of claim 12, wherein after repairing the battery according to the target repair strategy, the neuron network-based battery management system is further configured to:
obtain a current battery status of the battery;
compare the current battery status with a preset normal status to determine whether the battery has been successfully repaired; and
in response to determining that the battery has been successfully repaired, update the success rate of the target repair strategy, and recording information about a successful repair of the battery.

14. The neuron network-based battery management system of claim 13, wherein after determining whether the battery has been successfully repaired, the neuron network-based battery management system is further configured to:
in response to determining that the battery fails to be successfully repaired, generate a maintenance recommendation based on the fault type and display the maintenance recommendation;
or,
in response to determining that the battery fails to be successfully repaired, obtain a second repair strategy and repairing the battery according to the second repair strategy, wherein the second repair strategy is the repair strategy corresponding to the success rate ranked second in the descending order.

15. The neuron network-based battery management system of claim 9, wherein the battery comprises a plurality of monomer batteries, and the neuron network-based battery management system is further configured to:
acquire a current voltage of each of the plurality of monomer batteries;
perform an average calculation on the current voltages of the plurality of monomer batteries to obtain a current average voltage;
compare the current voltage of each monomer battery with the current average voltage;
if the current voltage of the monomer battery is greater than the current average voltage, control an equalization circuit to discharge the monomer battery until the current voltage of the monomer battery equals the current average voltage; and
if the current voltage of the monomer battery is less than the current average voltage, control the equalization circuit to charge the monomer battery until the current voltage of the monomer battery equals the current average voltage.

16. The neuron network-based battery management system of claim 9, wehrein the neuron network-based battery management system is further configured to:
detect an electrical current parameter of a charging current, and obtaining a current battery status of the battery;
adjust the electrical current parameter based on the current battery status to obtain a target electrical current parameter; and
adjust the charging current based on the target electrical current parameter, and supplying the adjusted charging current to the battery.

17. A neuron network-based battery management device, comprising:
at least one processor; and
a memory communicated to the at least one processor; wherein,
the memory stores instructions executable by the at least one processor, and the instructions, when executed by the at least one processor, cause the at least one processor to perform the neuron network-based battery management method of claim 1.
